(19) United States
(12) Patent Application Publication
(10) Pub. No.: US 2003/0194872 A1
(43) Pub. Date: Oct. 16, 2003

(54) Copper interconnect with sidewall copper-copper contact between metal and via

(75) Inventors: Suketu A. Parikh, San Jose, CA (US); Robin Cheung, Cupertino, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/124,588

(22) Filed: Apr. 16, 2002

(51) Int. Cl. H01L 21/311

(52) U.S. Cl. 438/694

(57) ABSTRACT

A method for forming a conductive feature on a substrate having a connection between the metal deposited in an interconnect opening and an underlying metal feature is presented. The underlying metal feature is etched and a barrier layer is deposited on the structure such that the metal deposited in the interconnect opening and the metal deposited in the metal feature are not isolated from each other by an intervening structure or layer.

### BACKGROUND OF THE INVENTION

1. Field of the Invention

Embodiments of the present invention generally relate to semiconductor substrate processing and integrated circuits. More particularly, the invention relates to a method of forming a semiconductor substrate having an area of contact between an underlying metal feature and an interconnect opening filled with metal.

2. Description of the Related Art

Modern semiconductor integrated circuits usually involve multiple conductive metal layers separated by dielectric (insulating) layers, such as silicon oxide or silica, often referred to simply as an oxide layer, although other materials are being considered for use as the dielectric. The metal layers are electrically interconnected by holes penetrating the intervening oxide layers that contact some underlying conductive feature. After the holes are etched, they are filled with a metal, such as aluminum or copper, to electrically connect the bottom layer with the top layer. The generic structure is referred to as a plug.

Plugs have presented an increasingly difficult problem as integrated circuits are formed with an increasing density of circuit elements because the feature sizes have continued to shrink. For logic applications, the thickness of the oxide layer seems to be constrained to the neighborhood of 1 μm, while the diameter of the plug is being reduced from the neighborhood of 0.35 μm or 0.25 μm to 0.18 μm and below. As a result, the aspect ratios (the ratio of the depth to the minimum lateral dimension) of the plugs are being pushed to 5:1 and above. As sizes continue to decrease, the characteristics of the material forming the plugs become increasingly important. The smaller the plug, the less resistive the material forming the plug should be for speed performance. Copper is a material which is becoming more important as a result. Copper has a resistivity of 1.7 μΩ.cm. Copper has a small RC time constant thereby increasing the speed of a device formed thereof. In addition, copper exhibits improved reliability over aluminum in that copper has excellent electromigration resistance and can drive more current in the lines.

One problem with the use of copper is that copper diffuses into silicon dioxide, silicon and other dielectric materials. Therefore, barrier layers become increasingly important to prevent copper from diffusing into the dielectric and compromising the integrity of the device. Unfortunately, barrier layers become incorporated into the fabricated structure and remain between two conductive features at their interface.

An example of a prior art dual damascene structure 10 which includes a barrier layer is shown in FIG. 1. The structure 10 includes a substrate 12 with an underlying metal feature 14. The structure further includes a first dielectric layer 16 and a second dielectric layer 18 which can be deposited and patterned by conventional dual damascene processes. The first dielectric layer 16 has a vertical interconnect opening 20 and the second dielectric layer 18 has a horizontal interconnect opening 22. A barrier layer 24 is deposited on the structure. By covering the sidewalls 26, 28 of the vertical interconnect opening and the horizontal interconnect opening, the barrier layer 24 helps prevent the diffusion of the metal 30 deposited in the vertical interconnect opening and the horizontal interconnect opening into the first dielectric layer 16 and the second dielectric layer 18. However, barrier layers deposited by currently used methods also typically cover the bottom 32 of the vertical interconnect opening, and thus separate the metal 30 deposited in the vertical interconnect opening from the underlying metal feature 14. The barrier layer at the bottom 32 of the vertical interconnect opening increases the resistance of the structure and detracts from the performance of the structure. The barrier layer at the bottom 32 of the via also prevents the formation of continuous metal grains between the underlying metal feature 14 and the metal 30 deposited in the vertical and horizontal interconnecting openings 20 and 22.

Therefore, there remains a need for a method of forming a semiconductor device that minimizes the detrimental effects that can be caused by barrier layers.

### SUMMARY OF THE INVENTION

The present invention generally provides a method for forming a conductive feature in a dual damascene structure formed over an underlying metal feature, comprising etching the metal feature, wherein etching the metal feature creates an undercut in the metal feature, depositing a barrier layer on the dual damascene structure by a line of sight process, and depositing a conductive metal and filling the dual damascene structure and the etched metal feature with the conductive metal.

In one embodiment, a method for forming a conductive feature on a substrate comprises providing a substrate including a metal feature, depositing an intermediate layer on the substrate, depositing a dielectric layer on the substrate, etching the dielectric layer to form an interconnect opening in the dielectric layer, etching the intermediate layer at the bottom of the interconnect opening to connect the interconnect opening and the metal feature, etching the metal feature, wherein etching the metal feature creates an undercut in the metal feature, depositing a barrier layer on the substrate by a line of sight process, and depositing a conductive metal and filling the interconnect opening and the etched metal feature with the conductive metal.

In one embodiment, the line of sight process comprises physical vapor deposition (PVD). Preferably, the barrier layer is deposited by physical vapor deposition of a material selected from the group consisting of Ta, TaN, W, WN, Ti, TiN, Co, and combinations thereof. In at least one embodiment, the metal feature comprises copper and the conductive metal comprises copper.

In at least one embodiment, the conductive metal is deposited by at least one of chemical vapor deposition, electroless deposition, PVD, electroplating.

In one embodiment, the method for forming a conductive feature on a substrate may further comprise annealing the deposited conductive material. In another embodiment, the method for forming a conductive feature on a substrate may further comprise chemical mechanical polishing or electropolishing the substrate.

A further embodiment comprises a method for forming a dual damascene structure, comprising providing a substrate including a metal feature, depositing a intermediate layer on the substrate, depositing a first dielectric layer on the substrate, depositing a second dielectric layer on the substrate, etching the first and second dielectric layers to form a vertical interconnect opening in the first dielectric layer and a horizontal interconnect opening in the second dielectric layer, etching the intermediate layer at the bottom of the vertical interconnect opening to connect the vertical interconnect opening and the metal feature, etching the metal feature, wherein etching the metal feature creates an undercut in the metal feature, depositing a barrier layer on the substrate by a line of sight process, and depositing a conductive metal and filling the horizontal interconnect opening, the vertical interconnect opening, and the etched metal feature with the conductive metal.

In another aspect, substrates such as semiconductor structures and dual damascene structures are provided.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a prior art dual damascene structure.

FIGS. 2-11 are structures prepared in accordance with embodiments of the invention.

FIG. 12 is a cross sectional view of a structure prepared in accordance with embodiments of the present invention.

FIG. 13 illustrates another structure prepared in accordance with embodiments of the present invention.

FIG. 14 is a prior art structure.

FIG. 15 is a structure prepared in accordance with an embodiment of the invention.

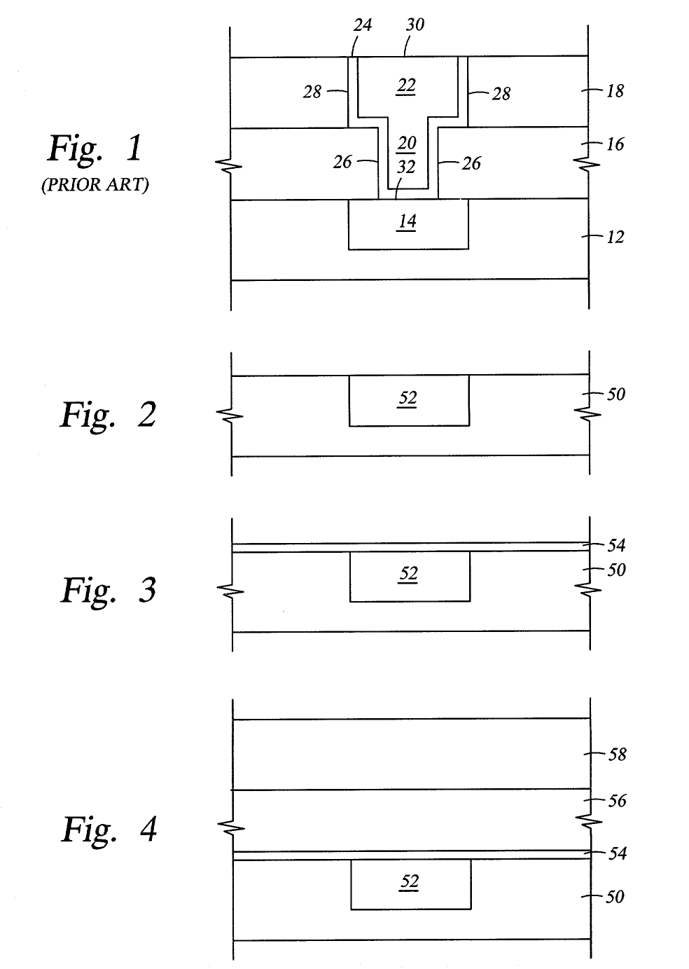

### DETAILED DESCRIPTION OF THE PREFERRED EMBODIMENT

The present invention generally provides a method for forming a device having an area of contact between an underlying metal feature and an interconnect opening filled with metal. Generally, an interface is opened between an underlying metal feature and an interconnect opening such that a barrier layer can be formed on portions of the device, such as portions of the dielectric layer, while a barrier layer is not formed on at least a portion of the interface between the underlying metal feature and the interconnect opening. In any or all of the embodiments described below, a barrier layer which separates the metal deposited in the interconnect opening(s) from the dielectric layers but does not completely separate the metal deposited in the interconnect opening(s) and the metal deposited in the etched metal feature is deposited by a line of sight process.

In one embodiment, a substrate 50 having an underlying metal feature 52 is provided, as shown in FIG. 2. While the metal feature 52 can include a variety of metals, the metal feature 52 preferably is or includes copper. As shown in FIGS. 3-5, an intermediate layer 54, such as a barrier layer and/or an etch stop, e.g., SiN, between the metal feature 52 and the vertical interconnect opening 62 is deposited on the substrate before first and second dielectric layers 56, 58 are deposited on the substrate. The dielectric layers may comprise oxides, carbon-doped oxides, low dielectric constant polymers, parylene-based materials, or combinations thereof. The dielectric layers may comprise porous oxides, carbon-doped oxides, low dielectric constant polymers, parylene-based materials, or combinations thereof. The etch stop may comprise silicon nitrides, silicon carbides, porous silicon nitrides or silicon carbides, or combinations thereof. A photoresist (not shown) or other conventional material may be used to pattern the first and second dielectric layers 56, 58.

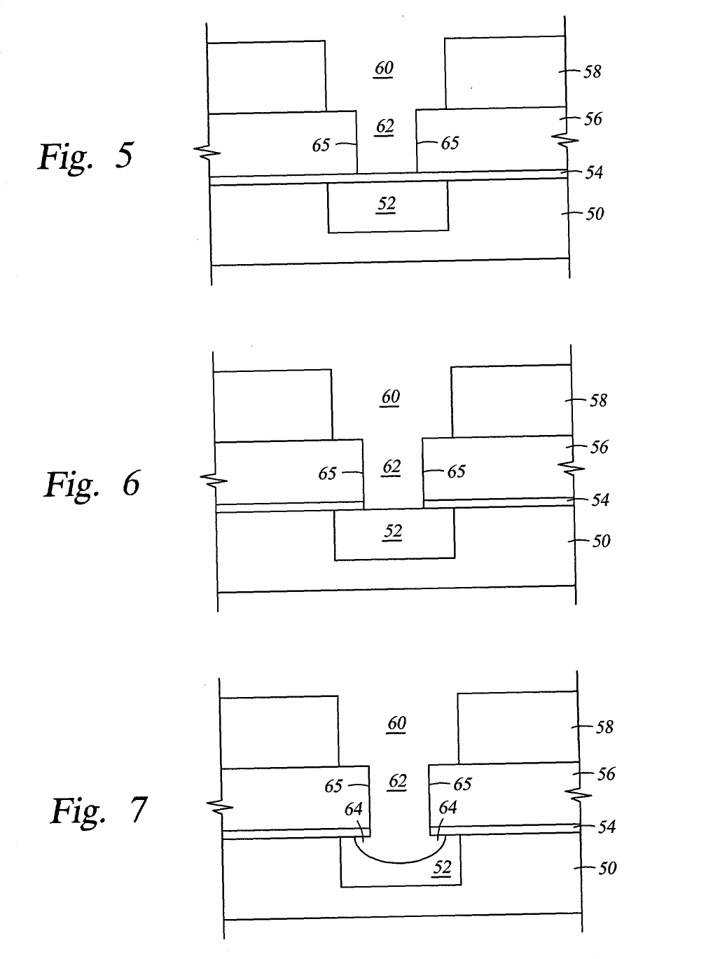

The second dielectric layer 58 and the first dielectric layer 56 are then etched, as shown in FIG. 5, such as by a dual damascene process. The etching of the second dielectric layer 58 creates a horizontal interconnect opening 60, and the etching of the first dielectric layer 56 creates a vertical interconnect opening 62 having sidewalls 65. The intermediate layer 54 is then etched using an etching material that does not significantly etch the dielectric layers 56, 58 and removed from the vertical interconnect opening 62. The vertical interconnect opening 62 is then connected to the horizontal interconnect opening 60 and the underlying metal feature 52, as shown in FIG. 6.

The underlying metal feature 52 is then etched such that a portion of the underlying metal feature is removed, as shown in FIG. 7. Removal of the portion of the underlying metal feature 52 results in undercuts 64 in the metal feature 52. While two undercuts 64 are shown, etching the underlying metal feature may create one or more undercuts in the metal feature. Furthermore, while two undercuts 64 are shown, the two undercuts 64 may be considered to be part of one annular undercut that is shown in cross section in the metal feature. While the undercuts 64 are shown as having a rounded shape, the undercuts may have other shapes depending on the etch characteristics of the material and the chemistry being used. The undercuts may extend laterally from between about 50 Å to about 1000 Å from the sidewalls 65 of the vertical interconnect opening 62 and away from the vertical interconnect opening 62. Preferably, the undercuts extend laterally from between about 200 Å to about 500 Å from the sidewalls 65 of the vertical interconnect opening 62 and away from the vertical interconnect opening 62. The undercuts may extend vertically down from between about 100 Å to about 2500 Å from the bottom of the etched vertical interconnect opening 62. Preferably, the undercuts extend vertically from between about 500 Å to about 1000 Å from the bottom of the etched vertical interconnect opening 62. While examples of undercut dimensions are described above, undercuts that have other dimensions may be used. Generally, a metal feature is etched such that the undercuts extend laterally away from the vertical interconnect opening, and thus, the undercuts can not be completely covered by a layer deposited by a line of sight process.

Several known types of processes may be used to etch the underlying metal feature. For example, a wet or a dry etch process may be used.

The etching chemistry used to etch the underlying metal feature should be one that will etch the metal feature but preferably will not etch the intermediate layer and will not etch the dielectric layers. Examples of materials, such as solutions, that can be used to perform a wet etch include nitric acid, sulfuric acid, hydrogen peroxide, and ammonium hydroxide. Solvents, such as EKD 265, NE 14, and ACT 970, may be used as etching solutions. Combinations of the etching solutions listed above may also be used. A wet etch can be performed in any sink or spray tool. The etching chemistry is applied for a period of time necessary to form an undercut. The etching period typically depends on the concentration of the etching chemistry used and/or the rate at which the etching chemistry etches the underlying metal feature. Generally, a wet etch is performed for between about 30 seconds to about one hour, e.g., between about 30 seconds to about 30 minutes, to achieve the desired amount of etching of the underlying metal feature. However, the etch process time is preferably minimized to increase throughput of substrates during processing. Examples of etching chemistries and etching periods that may be used include the following: EKC 265 for about 2 minutes, NE 14 for about 20 minutes, or ACT 970 for about 20 minutes.

An example of a material that can be used to perform a dry etch is a combination of a fluorine containing-gas, such as CHF₃ or C₂F₆, and O₂. Other gases that may be used to perform a dry etch include CₓH_{y}F_{z} gases, nitrogen, NF₃ and combinations thereof. A dry etch can be performed in any conventional etching or plasma chamber. An inductive plasma may be used in the chamber. The substrate is typically biased at between −1000 volts and 0 volts. The magnetic field of the chamber may be about 10 Gauss. The biasing of the substrate and the length of time of the etch may be varied as necessary to achieve the desired amount of etching in the underlying metal feature. Generally, a dry etch is performed for between about 10 seconds to about 2 minutes.

One example of a dry etch process to form undercuts in a metal feature includes biasing a substrate at between −1000 volts and 0 volts in a plasma chamber. The power applied to the chamber is about 1600 watts, and the magnetic field is about 10 Gauss. CF₄ is flowed into the chamber at about 20 sccm (standard cubic centimeters per minute). C₄F₆ is flowed into the chamber at about 25 sccm. O₂ is flowed into the chamber at about 20 sccm. Argon is flowed into the chamber at about 300 sccm. The substrate is plasma treated for about 30 seconds to form undercuts.

Alternatively, the underlying metal feature 52 may be etched by a sputter etch process such as a sputtering process used to pre-clean substrates before depositing layers of material on substrates. For example, the underlying metal feature 52 may be etched by bombarding the feature with sputtered argon, helium, hydrogen, other gases or ions, or combinations thereof for between about 10 seconds to about 2 minutes. One such process can be performed in a Pre-Clean II chamber available from Applied Materials, Inc., located in Santa Clara, Calif. An example of a pre-cleaning process that can be used to create undercuts includes flowing argon, such as at about 20 sccm into a chamber and creating a plasma in the chamber. The plasma activates the argon, and the argon bombards the substrate. The substrate is biased at between −1000 volts and 0 volts. The power applied to the chamber is about 300 watts. The substrate is plasma treated for about 30 seconds to form undercuts.

After the underlying metal feature 52 is etched, a barrier layer 66 is then deposited on the substrate, as shown in FIG. 8. Preferably, the barrier layer 66 is deposited by a line of sight process, i.e., a process in which the material that is deposited on the substrate is primarily deposited on the portions of the substrate that are visible from the processing area that is above the substrate and through which the source of the material to be deposited is provided. Line of sight processes that may be used include PVD, ionized PVD, or self-ionized PVD according to methods known in the art. However, other line of sight processes may also be used. The barrier layer 66 that is deposited by any of these processes is preferably selected from the group of Ta, TaN, W, WN, Ti, TiN, Co, and combinations thereof. The barrier layer 66 deposited by a line of sight process will not cover the sides of the undercuts 64 in the metal feature 52 because the undercuts are underneath the first dielectric layer 56, rather than underneath the vertical interconnect opening and thus, not in the line of sight of the material being directionally deposited. Thus, while a portion 68 of the barrier layer 66 may cover a portion of the underlying metal feature 52, as shown in FIG. 8, the barrier layer does not completely separate the vertical interconnect opening 62 and the underlying metal feature 52 because of the gaps in the barrier layer around the undercuts 64 and the portion 68 of the barrier layer 66 on the underlying metal feature 52.

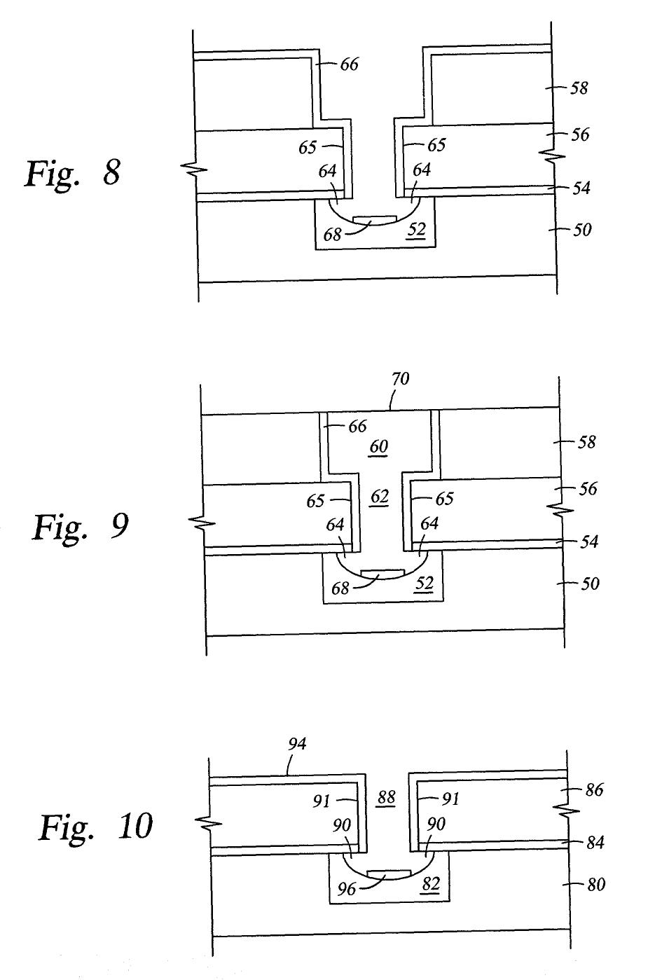

After the barrier layer is deposited, a conductive metal 70 is deposited in and fills the etched metal feature, the vertical interconnect opening, and the horizontal interconnect opening, as shown in FIG. 9. Preferably, the underlying metal feature 52 is or includes copper and the metal 70 deposited is or includes copper. In at least one embodiment, the metal 70 can be deposited by chemical vapor deposition (CVD). In another embodiment, the metal 70 can be deposited by electroless deposition. In another embodiment, the metal 70 can be deposited by forming a seed layer using PVD or CVD followed by bulk fill using electroplating techniques. In each of these embodiments, the method of metal deposition can be used to fill non-line of site structures, such as the undercuts 64. While examples of undercut dimensions are discussed above, the undercuts in any of the embodiments described herein may have other dimensions that may be filled with the metal 70 using the processes described herein.

After the metal 70 is deposited, the metal can be annealed to optimize the size and uniformity of the metal grains. Annealing may also enhance the flow and distribution of the metal 70 into the undercuts 64. The substrate can also undergo chemical mechanical polishing (CMP) or electropolishing to remove any excess metal on the substrate and to provide a substrate with a uniform surface, as shown in FIG. 9.

In another embodiment, a dual damascene structure formed over a metal feature is provided. The dual damascene structure includes a vertical interconnect opening 62 connected to horizontal interconnect opening 60 and underlying metal feature 52, as shown in FIG. 6. As shown and described above with respect to FIGS. 7-9, the underlying metal feature 52 is etched such that undercuts are created in the metal feature. A barrier layer 66 is deposited on the dual damascene structure by a line of sight process. A conductive metal 70 is deposited on and fills the dual damascene structure and the etched metal feature with the conductive metal.

In yet another embodiment, shown in FIG. 10, a substrate 80 has an underlying metal feature 82 and an intermediate layer 84, such as a barrier layer and/or an etch stop, e.g., SiN, deposited on the substrate. A dielectric layer 86 is then deposited on the substrate. The dielectric layer is etched to form an interconnect opening 88. The intermediate layer 84 is then etched using an etching material that does not significantly etch the dielectric layer and removed from the bottom of the interconnect opening 88 such that the underlying metal feature 82 and the interconnect opening 88 are connected. The underlying metal feature is then etched such that only a portion of the underlying metal feature is removed, and undercuts 90 are created in the underlying metal feature. While two undercuts 90 are shown, etching the underlying metal feature may create one or more undercuts in the metal feature. Furthermore, while two undercuts 90 are shown, the two undercuts 90 may be considered to be part of one annular undercut that is shown in cross section in the metal feature. After the underlying metal feature 82 is etched, a barrier layer 94 is then deposited on the substrate. Preferably, the barrier layer 94 is deposited by a line of sight process, i.e., a process in which the material that is deposited on the substrate is primarily deposited on the portions of the substrate that are visible from the processing area that is above the substrate and provides the source of the material to be directionally deposited. Line of sight processes that may be used include PVD, ionized PVD, or self-ionized PVD according to methods known in the art. However, other line of sight processes may also be used. The barrier layer 94 that is deposited by any of these processes is preferably selected from the group of Ta, TaN, W, WN, Ti, TiN, Co, and combinations thereof. The barrier layer 94 deposited by a line of sight process will not cover the sides of the undercuts 90 in the metal feature 82 because the undercuts are underneath the dielectric layer 86 and extend away from the sidewalls 91 of the interconnect opening 88, and thus, are not in the line of sight of the material being directionally deposited. Thus, while a portion 96 of the barrier layer 94 may cover a portion of the underlying metal feature 82, as shown in FIG. 10, the barrier layer does not completely separate the interconnect opening 88 and the underlying metal feature 82 because of the gaps in the barrier layer around the undercuts 90 and the portion 96 of the barrier layer 94 on the underlying metal feature 82.

The deposition and etching steps described herein for the substrate 80 are performed according to processes similar or identical to those described with respect to dual damascene structures, and further processing steps similar or identical to the processes described above with respect to dual damascene structures may be performed on the substrate. For example, in one embodiment, a conductive metal (not shown) is deposited in and fills the etched metal feature and the interconnect opening. Preferably, the underlying metal feature comprises copper and the metal deposited comprises copper. CVD, electroless deposition, PVD followed by electroplating, and electroplating are methods that may be used to deposit the conductive metal. In each of these embodiments, the method of metal deposition can be used to fill non-line of sight structures, such as the undercuts 90. After the metal is deposited, the metal may be annealed. The substrate may also be treated with CMP or an electropolish etch to remove any excess metal on the substrate and to provide a substrate with a uniform surface.

While the embodiments described above are shown with respect to figures in which the underlying metal feature has a greater width than the vertical interconnect opening, the processes described herein may also be performed on substrates having an underlying metal feature with the same width as the vertical interconnect opening in one plane or on substrates having unlanded vertical interconnect openings such as substrates having an underlying metal feature that extends on one side horizontally beyond the area underneath the vertical interconnect opening.

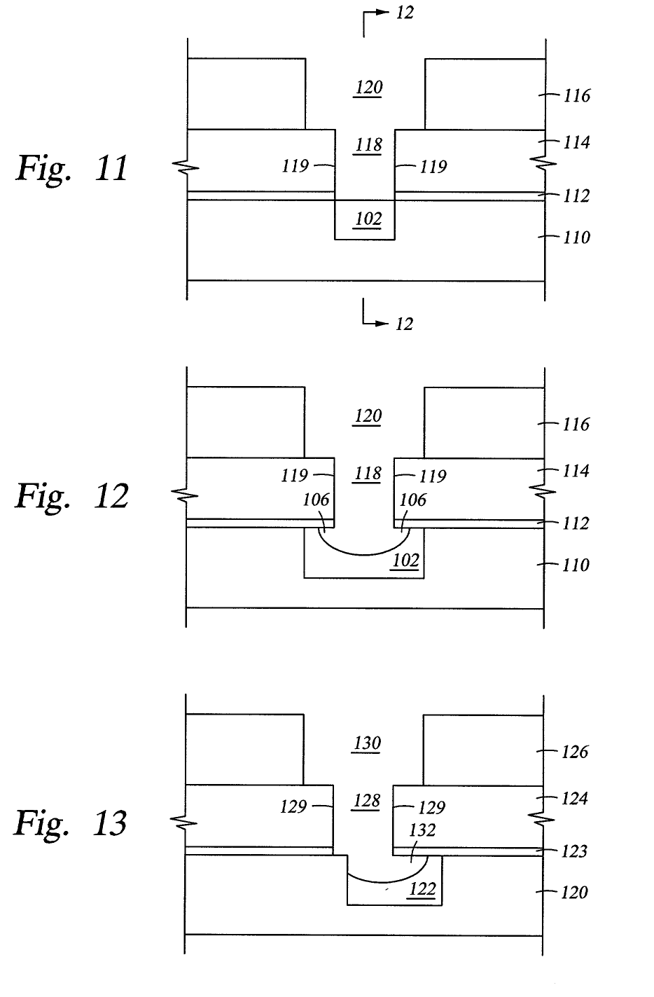

An example of a substrate having an underlying metal feature having the same width as a vertical interconnect opening in one plane is shown in FIG. 11. The substrate 110 includes an underlying metal feature 102, an intermediate layer 112 deposited on the substrate, a first dielectric layer 114, a second dielectric layer 116, a vertical interconnect opening 118 having sidewalls 119, and a horizontal interconnect opening 120. The underlying metal feature 102 is the same or approximately the same width as the vertical interconnect opening 118 in the plane and cross section shown in FIG. 11. However, in a view of the plane and cross section taken along 12-12, shown in FIG. 12, the underlying metal feature 102 and the vertical interconnect opening 118 do not have the same width. The underlying metal feature 102 is wider than the vertical interconnect opening 104, and thus, one or more undercuts 106 can be created in the underlying metal feature by the processes described above.

An example of a substrate having an unlanded vertical interconnect opening, e.g., a substrate having an underlying metal feature that extends on one side horizontally beyond the area underneath the vertical interconnect opening, is shown in FIG. 13. The substrate 120 includes an underlying metal feature 122, an intermediate layer 123 deposited on the substrate, a first dielectric layer 124, a second dielectric layer 126, a vertical interconnect opening 128 having sidewalls 129, and a horizontal interconnect opening 130. The underlying metal feature 122 is partially underneath the vertical interconnect opening 128 and partially underneath a first dielectric layer 124 and the intermediate layer 123 on the substrate on one side of the vertical interconnect opening. The portion of the underlying metal feature 122 underneath the first dielectric layer 124 can be etched to form an undercut 132 using the processes described above.

The processes described herein can be used to prepare devices, i.e., structures, having a more continuous grain formation than devices prepared according to traditional techniques in which the underlying metal feature of a device is completely separated from the metal deposited in the device interconnects by a barrier layer. The barrier layers deposited by the processes described herein do not completely separate the underlying metal feature and the metal deposited in the interconnects, and thus, continuous metal grains may be formed between the underlying metal feature and the metal deposited in the interconnects. The connection and continuous grain between the underlying metal feature and the metal deposited in the interconnects may also enhance electromigration within the metal of the device and may improve the thermal stress reliability of the device. Furthermore, the undercuts created by the processes described herein result in a large surface area between the underlying metal feature and the metal deposited in the interconnects. The large surface area between the underlying metal feature and the metal deposited in the interconnects typically decreases the resistance of the device.

The processes described herein also provide devices which are less likely to lose their metal plugs because of the direct connection between the metal plugs in the interconnect openings and the underlying metal feature. Thus, the metal plugs are more deeply anchored in the substrate than metal plugs formed according to conventional processes. Furthermore, the metal which is deposited in the undercut(s) of the underlying metal feature helps anchor the metal deposited in the interconnect openings and the underlying metal feature by creating a deposited metal structure which is bigger, i.e., wider that the vertical interconnect opening.

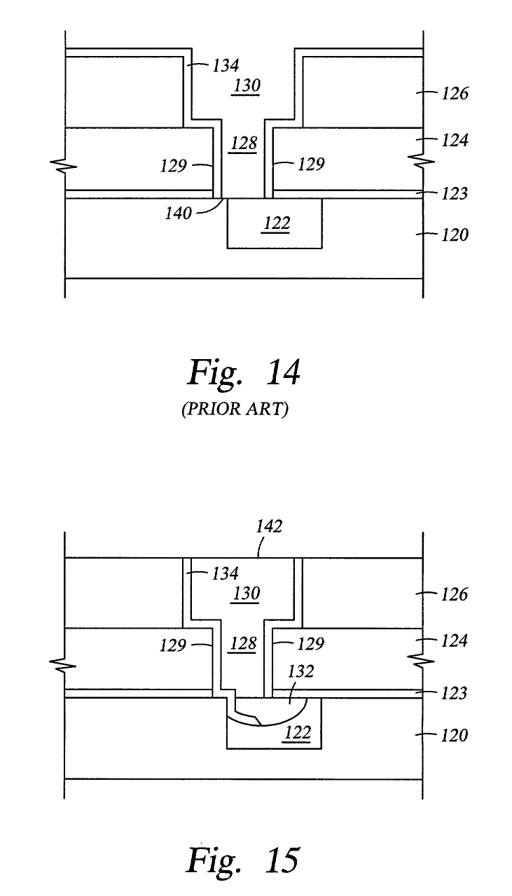

While attempts have been made to provide a continuous connection between an underlying metal feature and the metal deposited in an unlanded vertical interconnect opening by selectively etching the barrier layer 134 from the bottom of the vertical interconnect opening, these processes can result in the removal of barrier layer from the substrate so that there is no barrier layer 134 between the metal deposited in the unlanded vertical interconnect opening and the substrate, as shown in region 140 of FIG. 14. A structure having an unlanded vertical interconnect opening and produced by the processes described herein and shown in FIG. 15 does not have the exposed region. The barrier layer 134 does not completely separate the metal 142 deposited in the horizontal interconnect opening 130, the vertical interconnect opening 128, and the underlying metal feature 122 from the metal already present in the underlying metal feature 122 because the undercut 132 in the underlying metal feature is not covered by the barrier layer 134.

While the foregoing is directed to embodiments of the present invention, other and further embodiments of the invention may be devised without departing from the basic scope thereof, and the scope thereof is determined by the claims that follow.

What is claimed is:

1. A method for forming a conductive feature in a dual damascene structure formed over an underlying metal feature, comprising:
etching the metal feature, wherein etching the metal feature creates an undercut in the metal feature;
depositing a barrier layer on the dual damascene structure by a line of sight process; and
depositing a conductive metal and filling the dual damascene structure and the etched metal feature with the conductive metal.

2. The method of claim 1, wherein the line of sight process comprises physical vapor deposition.

3. The method of claim 2, wherein the barrier layer is deposited by physical vapor depositing a material selected from the group of Ta, TaN, W, WN, Ti, TiN, Co, and combinations thereof.

4. The method of claim 1, wherein the metal feature comprises copper and the conductive metal comprises copper.

5. The method of claim 1, wherein the conductive metal is deposited by at least one of chemical vapor deposition, electroless deposition, physical vapor deposition, and electroplating.

6. The method of claim 5, further comprising annealing the deposited conductive metal.

7. The method of claim 6, further comprising chemical mechanical polishing the structure.

8. The method of claim 6, further comprising electropolishing the structure.

9. The method of claim 1, wherein the dual damascene structure comprises an interconnect opening connected to the metal feature, and the metal feature is etched such that the undercut extends laterally away from the interconnect opening.

10. The method of claim 9, wherein the undercut extends laterally from between about 50 Å to about 1000 Å away from the interconnect opening.

11. The method of claim 10, wherein the undercut extends laterally from between about 200 Å to about 500 Å away from the interconnect opening.

12. The method of claim 1, wherein the metal feature is etched with a solution.

13. The method of claim 12, wherein the solution comprises a material selected from the group consisting of sulfuric acid, nitric acid, hydrogen peroxide, ammonium hydroxide, EKC 265, NE 14, ACT 970, and combinations thereof.

14. The method of claim 13, wherein the metal feature is etched for about 2 minutes with a solution comprising EKC 265.

15. The method of claim 13, wherein the metal feature is etched for about 20 minutes with a solution comprising NE 14.

16. The method of claim 13, wherein the metal feature is etched for about 20 minutes with a solution comprising ACT 970.

17. The method of claim 12, wherein the metal feature is etched for between about 30 seconds to about one hour.

18. The method of claim 17, wherein the metal feature is etched for between about 30 seconds to about 30 minutes.

19. The method of claim 1, wherein the metal feature is etched by a dry etch process.

20. The method of claim 19, wherein the metal feature is etched using at least one material selected from the group consisting of CHF₃, C₂F₆, O₂, CF₄, C₄F₆, CₓH_{y}F_{z} gases, nitrogen, NF₃, and combinations thereof.

21. The method of claim 19, wherein the structure is biased at between about −1000 volts and about 0 volts.

22. The method of claim 19, wherein the metal feature is etched for between about 10 seconds and about 2 minutes.

23. The method of claim 1, wherein the metal feature is etched by a sputtering process.

24. The method of claim 23, wherein the sputtering process comprises sputtering a material selected from the group consisting of argon, helium, hydrogen, and combinations thereof.

25. The method of claim 23, wherein the structure is biased at between about −1000 volts and about 0 volts.

26. The method of claim 23, wherein the metal feature is etched for between about 10 seconds and about 2 minutes.

27. A method for forming a conductive feature on a substrate, comprising:
providing a substrate including a metal feature;
depositing a intermediate layer on the substrate;
depositing a dielectric layer on the substrate;
etching the dielectric layer to form an interconnect opening in the dielectric layer;
etching the intermediate layer at the bottom of the interconnect opening to connect the interconnect opening and the metal feature;
etching the metal feature, wherein etching the metal feature creates an undercut in the metal feature;
depositing a barrier layer on the substrate by a line of sight process;
and depositing a conductive metal and filling the interconnect opening and the etched metal feature with the conductive metal.

28. The method of claim 27, wherein the line of sight process comprises physical vapor deposition.

29. The method of claim 28, wherein the barrier layer is deposited by physical vapor deposition of a material selected from the group of Ta, TaN, W, WN, Ti, TiN, Co, and combinations thereof.

30. The method of claim 27, wherein the metal feature comprises copper and the conductive metal comprises copper.

31. The method of claim 27, wherein the conductive metal is deposited by at least one of chemical vapor deposition, electroless deposition, physical vapor deposition, and electroplating.

32. The method of claim 27, further comprising annealing the deposited conductive metal.

33. The method of claim 27, further comprising chemical mechanical polishing the substrate.

34. The method of claim 27, further comprising electropolishing the substrate.

35. The method of claim 27, wherein the metal feature is etched such that the undercut extends laterally away from the interconnect opening.

36. The method of claim 35, wherein the undercut extends laterally from between about 50 Å to about 1000 Å away from the interconnect opening.

37. The method of claim 36, wherein the undercut extends laterally from between about 200 Å to about 500 Å away from the interconnect opening.

38. The method of claim 27, wherein the metal feature is etched with a solution.

39. The method of claim 38, wherein the solution comprises a material selected from the group consisting of sulfuric acid, nitric acid, hydrogen peroxide, ammonium hydroxide, EKC 265, NE 14, ACT 970, and combinations thereof.

40. The method of claim 39, wherein the metal feature is etched for about 2 minutes with a solution comprising EKC 265.

41. The method of claim 39, wherein the metal feature is etched for about 20 minutes with a solution comprising NE 14.

42. The method of claim 39, wherein the metal feature is etched for about 20 minutes with a solution comprising ACT 970.

43. The method of claim 27, wherein the metal feature is etched for between about 30 seconds to about one hour.

44. The method of claim 43, wherein the metal feature is etched for between about 30 seconds to about 30 minutes.

45. The method of claim 27, wherein the metal feature is etched by a dry etch process.

46. The method of claim 45, wherein the metal feature is etched using at least one material selected from the group consisting of CHF₃, C₂F₆, O₂, CF₄, C₄F₆, CₓH_{y}F_{z} gases, nitrogen, NF₃, and combinations thereof.

47. The method of claim 45, wherein the structure is biased at between about −1000 volts and about 0 volts.

48. The method of claim 45, wherein the metal feature is etched for between about 10 seconds and about 2 minutes.

49. The method of claim 27, wherein the metal feature is etched by a sputtering process.

50. The method of claim 49, wherein the sputtering process comprises sputtering a material selected from the group consisting of argon, helium, hydrogen, and combinations thereof.

51. The method of claim 49, wherein the structure is biased at between about −1000 volts and about 0 volts.

52. The method of claim 49, wherein the metal feature is etched for between about 10 seconds and about 2 minutes.

53. A method for forming a dual damascene structure, comprising:
providing a substrate including a metal feature;
depositing a intermediate layer on the substrate;
depositing a first dielectric layer on the substrate;
depositing a second dielectric layer on the substrate;
etching the first and second dielectric layers to form a vertical interconnect opening in the first dielectric layer and a horizontal interconnect opening in the second dielectric layer;
etching the intermediate layer at the bottom of the vertical interconnect opening to connect the vertical interconnect opening and the metal feature;
etching the metal feature, wherein etching the metal feature creates an undercut in the metal feature;
depositing a barrier layer on the substrate by a line of sight process; and
depositing a conductive metal and filling the horizontal interconnect opening, the vertical interconnect opening, and the etched metal feature with the conductive metal.

54. The method of claim 53, wherein the line of sight process comprises physical vapor deposition.

55. The method of claim 54, wherein the barrier layer is deposited by physical vapor deposition of a material selected from the group of Ta, TaN, W, WN, Ti, TiN, Co, and combinations thereof.

56. The method of claim 53, wherein the metal feature comprises copper and the conductive metal comprises copper.

57. The method of claim 53, wherein the conductive metal is deposited by at least one of chemical vapor deposition, electroless deposition, physical vapor deposition, and electroplating.

58. The method of claim 53, further comprising annealing the deposited conductive metal.

59. The method of claim 53, further comprising chemical mechanical polishing the substrate.

60. The method of claim 53, further comprising electropolishing the substrate.

61. The method of claim 53, wherein the metal feature is etched such that the undercut extends laterally away from the interconnect opening.

62. A semiconductor structure, comprising:
a substrate including an etched metal feature;
an intermediate layer;
a first dielectric layer;
a first interconnect opening extending through the first dielectric layer and the intermediate layer and connected to the metal feature, the metal feature having an undercut; and
a barrier layer that covers a portion of the metal feature underneath the first interconnect opening, the barrier layer being deposited such that it does not cover the undercut in the metal feature.

63. The semiconductor structure of claim 62, further comprising:
a second dielectric layer; and
a second interconnect opening extending through the second dielectric layer, wherein the second interconnect opening is connected to the first interconnect opening.

64. A dual damascene structure formed by a process comprising:
providing a substrate including a metal feature;
depositing a intermediate layer on the substrate;
depositing a first dielectric layer on the substrate;
depositing a second dielectric layer on the substrate;
etching the first and second dielectric layers to form a vertical interconnect opening in the first dielectric layer and a horizontal interconnect opening in the second dielectric layer;
etching the intermediate layer at the bottom of the vertical interconnect opening to connect the vertical interconnect opening and the metal feature;
etching the metal feature, wherein etching the metal feature creates an undercut in the metal feature;
depositing a barrier layer on the substrate by a line of sight process; and
depositing a conductive metal and filling the horizontal interconnect opening, the vertical interconnect opening, and the etched metal feature with the conductive metal.
